(19) United States
(12) Patent Application Publication
(10) Pub. No.: US 2025/0209237 A1
(43) Pub. Date: Jun. 26, 2025

(54) AI-BASED TECHNOLOGIES FOR MODIFYING PROPERTIES OF FINITE ELEMENT STRUCTURES

(71) Applicant: VOLKSWAGEN GROUP OF AMERICA, INC., Reston, VA (US)

(72) Inventors: Wesley TESKEY, Foster City, CA (US); Edward MICHAUD, Knoxville, TN (US); Megan HARDY, San Francisco, CA (US); Gianina Alina NEGOITA, San Leandro, CA (US); Dayakar PENUMADU, Knoxville, TN (US)

(21) Appl. No.: 18/396,151

(22) Filed: Dec. 26, 2023

(51) Int. Cl. G06F 30/23; G06N 3/04

(52) U.S. Cl. CPC G06F 30/23; G06N 3/04

(57) ABSTRACT

Embodiments provide technologies for improving structural properties of a finite element structure. A computing system builds, from a plurality of graph representations of a corresponding finite element mesh, a graph neural network (GNN). The computing system may use the GNN or other methods to traverse the graph representation. In traversing the graph representation, the computing system evaluates, for each grouping of nodes in the representation, one or more properties associated with the structural element. The computing system determines whether the structural element satisfies a specified condition. Upon so determining, the computing system modifies the grouping of nodes and outputs the resulting graph representation.

The present disclosure generally relates to finite element analysis (FEA), and more specifically, to modifying normalized properties associated with structural response of finite element structures using artificial intelligence-based techniques.

### BACKGROUND

In engineering design, such as for vehicular components for automobiles, finite element analysis (FEA) provides important consideration and input to design aspects. Whether in collision analysis, fatigue analysis, electromagnetic shielding consideration, or otherwise, FEA enables designers to appreciate advantages and disadvantages of geometries, materials, and other components. However, traditional FEA is often time consuming and typically requires intensive simulation applying considerable computational resources.

### SUMMARY

According to an aspect of the present disclosure, a method includes receiving, by one or more processors, a graph representation of a finite element mesh, the graph representation including a plurality of groupings of nodes, each grouping of nodes corresponding to a structural element of the finite element mesh. The graph representation is traversed. For each of the plurality of groups of nodes, (i) one or more properties associated with the structural element is evaluated; (ii) based on the evaluation, it is determined whether the structural element satisfies a specified condition; and (iii) upon determining that the structural element satisfies the specified condition, the grouping of nodes in the graph representation is modified based on the evaluation. The traversed graph representation is output.

Additional features of the present disclosure will become apparent to those skilled in the art upon consideration of illustrative embodiments exemplifying the best mode of carrying out the disclosure as presently perceived.

### BRIEF DESCRIPTION OF THE DRAWINGS

The detailed description particularly refers to the accompanying figures in which:

FIG. 1 is a block diagram of an example computing system configured to perform finite element analysis and structural or functional modification using artificial intelligence (AI)-based techniques, according to illustrative embodiments within the present disclosure;

FIG. 2 is a conceptual diagram of an operating environment of the computing system of FIG. 1 for performing finite element analysis and structural modification using AI-based techniques, according to illustrative embodiments within the present disclosure;

FIGS. 3A-3C are conceptual diagrams depicting graph-based modification of properties of a finite element structure, according to illustrative embodiments within the present disclosure;

FIGS. 4A-4C are conceptual diagrams depicting further graph-based modification of properties of a finite element structure, according to illustrative embodiments within the present disclosure; and

FIG. 5 is a flow diagram of an example method for modifying structural properties of a finite element structure using AI-based techniques, according to illustrative embodiments within the present disclosure.

### DETAILED DESCRIPTION

Component design (e.g., vehicular component design) can benefit from rigorous finite element analysis. For example, whether in load testing, collision simulation, stress/strain/fatigue analysis, electromagnetic shielding consideration, heat resistance analysis, vibration effects, fluid flows, chemical/UV exposure analysis, or otherwise, thorough development in consideration of these aspects can yield design improvements to performance, cost, and/or failure rates. Finite element analysis (FEA) can allow evaluation of advantages and disadvantages of geometries, materials, coatings, collective operations, or other component aspects.

Traditional FEA simulations require considerable time and computing resources. More particularly, FEA involves computing operations that process systems of equations (typically partial differential equations) that represent the physical behavior of a given system, in which the amount of equations to process and unknown variables to identify increases the larger or more complex that the structure is. Consequently, near immediate feedback concerning designs can be challenging to obtain, which potentially extends the design process and consumes computing resources. To address such shortcomings, artificial intelligence (AI) and machine learning-based approaches have been proposed for simulating FEA. However, current AI and machine learning-based approaches, while able to perform FEA more quickly relative to traditional methods, can vary significantly in terms of accuracy of a given result structural model and thus result in increased error over time.

Embodiments presented herein disclose techniques for modifying structural and/or functional properties of finite element structural models using AI- and machine learning-based methods. Given that material structures may be represented as finite element graphs, the techniques may train AI- and machine learning-based methods such as graph neural networks to evaluate such structures and identify areas (groupings of nodes) of targeted mechanical stress and strain and expand or contract the structure accordingly to generate potentially improved finite element structures (e.g., a structure with areas having a specific stress measure or range, a specific stiffness measure or range, and so on). As further described herein, a computing system executing an AI engine (or some software, hardware, or circuitry capable of performing the techniques of the present disclosure) may receive, as input, a numerous amount of material structures as training data and perform the finite element analysis on each of the structures. Generally, doing so will result one or more structures as output which can serve as an approximation for an improved structure. The computing system may then perform finite element simulation on such structures to obtain an improved structure. The improved structure may thereafter be adapted into a design of a component (such as a vehicular component) and finalized into a physical component.

In an embodiment, the computing device may take output structures from the AI engine that have undergone finite element simulation and use the outputs as additional training data for refining the performance of the AI engine. This training data, which would typically comprise thousands of structures modified as per above, can be useful for training the AI engine because the structures generated would have the types of properties that the AI engine is trying to optimize (such as increased normalized properties with its density such as specific stiffness and increased specific strength). As a result, techniques disclosed herein can provide a training loop for the AI engine such that material structures that have undergone finite element simulation can be used as training data for more effective subsequent analysis by the AI engine.

Advantageously, techniques presented herein can allow computing systems to create new structures that would be difficult or impossible to achieve under current technological approaches of design. Using AI and machine learning techniques as disclosed herein further enables computing systems to generate such structures that are otherwise difficult to undertake at a high speed and/or under relatively efficient consumption of computational resources, compared to more traditional FEA software methods which undertake analysis and generation much more slowly.

Note, the present disclosure references vehicular design (e.g., design of vehicular components such as battery cases, interior equipment, and the like) as an example in which AI-based structural and functional modification of finite element structural properties may be deployed. However, one of skill in the art will recognize that the embodiments disclosed herein may be adapted to a variety of uses, such as in designing other parts of a vehicle, acro-thermal structures, aerospace structures, buildings, bridges, and infrastructure. Generally, the embodiments disclosed herein may be adapted to situations in which mechanical FEA is used.

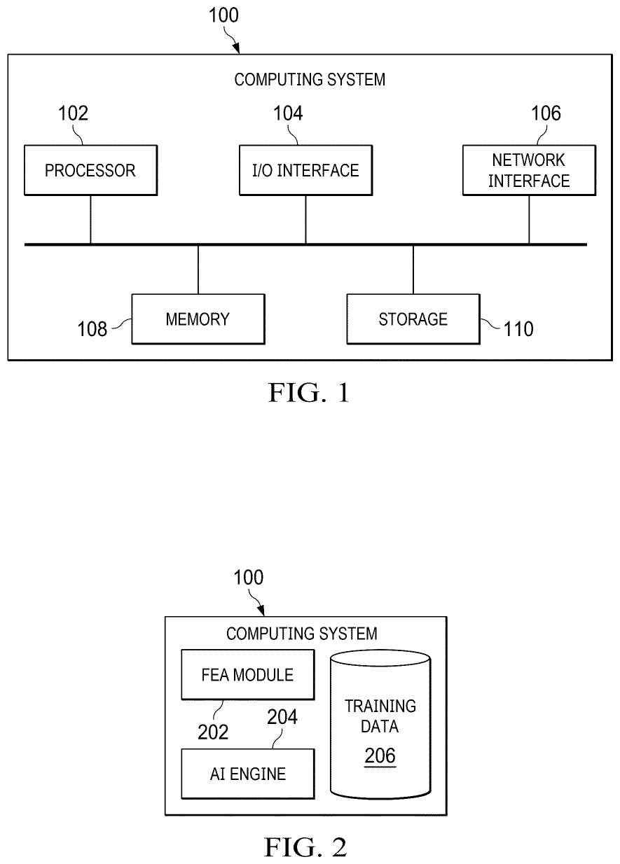

Referring now to FIG. 1, a block diagram of components of a computing system 100 incorporating the embodiments of the present disclosure is now shown. Illustratively, the computing system 100 includes a processor 102, input/output (I/O) interface 104, network interface 106, memory 108, and a storage 110, each interconnected via a hardware bus. In practice, the computing system 100 will include additional hardware components not shown.

In an embodiment, the processor 102 retrieves and executes programming instructions stored in the memory 108. The processor 102 may be embodied as one or more processors, each processor being a type capable of performing the functions described herein. For example, the processor 102 may be embodied as a single or multi-core processor(s), a microcontroller, microprocessors, or other processor or processing/controlling circuit. In some embodiments, the processor 102 may be embodied as, include, or be coupled to a field programmable gate array (FPGA), an application-specific integrated circuit (ASIC), reconfigurable hardware or hardware circuitry, or other specialized hardware to facilitate performance of the functions described herein.

The hardware bus is used to transmit instructions and data between the processor 102, I/O interface 104, network interface 106, the memory 108, and the storage 110. The processor 102 is included to be representative of a single CPU, multiple CPUs, a single CPU having multiple processing cores, and the like.

The I/O interface 104 allows I/O devices (e.g., keyboards, mouse devices, printers, sensors, etc.) to communicate with hardware and software components of the computing system 100. For example, the I/O interface 104 may be embodied as, or otherwise include, memory controller hubs, input/output control hubs, integrated sensor hubs, firmware devices, communication links (e.g., point-to-point links, bus links, wires, cables, light guides, printed circuit board traces, etc.), and/or other components and subsystems to facilitate the input/output operations. In some embodiments, the I/O interface 104 may form a portion of a system-on-a-chip (SoC) and be incorporated, along with one or more of the processor 102, the memory 108, and other components of the computing system 100.

The network interface 106 may be embodied as any hardware, software, or circuitry (e.g., a network interface card) used to connect the computing system 100 over a network and providing network communication component functions. For example, the network interface 106 may be embodied as any communication circuit, device, or collection thereof, capable of enabling communications over the network between the computing system 100 and other devices (e.g., systems storing training data for AI and ML methods, systems for performing certain aspects of the present disclosure including pre-processing finite element structure data, etc.). The network interface 106 may be configured to use any one or more communication technology (e.g., wired, wireless, and/or cellular communications) and associated protocols (e.g., Ethernet, Bluetooth®, Wi-Fi®, WiMAX, 5G-based protocols, etc.) to effect such communication. For example, to do so, the network interface 106 may include a network interface controller (NIC, not shown), embodied as one or more add-in-boards, daughtercards, controller chips, chipsets, or other devices that may be used for network communications with remote devices. For example, the NIC may be embodied as an expansion card coupled to an I/O device interface over an expansion bus such as PCI Express.

The memory 108 corresponds to a computer-readable storage media storing instructions for performing the functions described herein. The memory 108 may be embodied as any type of volatile (e.g., dynamic random access memory, etc.) or non-volatile memory (e.g., byte addressable memory) or data storage capable of performing the functions described herein. Volatile memory may be a storage medium that requires power to maintain the state of data stored by the medium. Non-limiting examples of volatile memory may include various types of random access memory (RAM), such as DRAM or static random access memory (SRAM). One particular type of DRAM that may be used in a memory module is synchronous dynamic random access memory (SDRAM). In particular embodiments, DRAM of a memory component may comply with a standard promulgated by JEDEC, such as JESD79F for DDR SDRAM, JESD79-2F for DDR2 SDRAM, JESD79-3F for DDR3 SDRAM, JESD79-4A for DDR4 SDRAM, JESD209 for Low Power DDR (LPDDR), JESD209-2 for LPDDR2, JESD209-3 for LPDDR3, and JESD209-4 for LPDDR4. Such standards (and similar standards) may be referred to as DDR-based standards and communication interfaces of the storage devices that implement such standards may be referred to as DDR-based interfaces.

The storage 110 may be embodied as any type of devices configured for short-term or long-term storage of data such as, for example, memory devices and circuits, memory cards, hard disk drives (HDDs), solid-state drives (SSDs), or other data storage devices. The storage 110 may include a system partition that stores data and firmware code for the storage 110. The storage 110 may also include an operating system partition that stores data files and executables for an operating system.

As stated, the present disclosure includes operation of machine learning and/or generative artificial intelligence modules, which can include execution of instructions stored on the memory 108 by the processor 102 to conduct such operations, and may include communication circuitry to communicate governing and/or facilitating signals to and/or from other devices and/or systems.

In an embodiment, the computing system 100 may correspond to a physical computing system (e.g., desktop computer, laptop computer, mobile device, rack server, etc.). In other embodiments, the computing system 100 may correspond to a virtual computing system, such as a virtual machine instance executing on a cloud network platform, a pooling of compute and storage resources in a network location, and the like, in which the processor 102, I/O interface 104, network interface 106, memory 108, and storage 110 are virtual components that perform identical functions of a physical processor, network interface, memory, and storage, respectively.

Referring now to FIG. 2, the computing system 100, in operation, may provide an operating environment for performing the techniques of the present disclosure. As shown, the operating environment includes finite element analysis (FEA) module 202, an AI engine 204, and training data 206. The geometric input data to the FEA module can be based on a pre-processor or a one-dimensional (1D), two-dimensional (2D), or three-dimensional (3D) scanned object information, such as appropriate resolution x-ray computed tomography-based digital data.

The illustrative FEA module 202 may be embodied as any hardware, software, or circuitry for analyzing and simulating behavior of material structures and systems. For instance, the FEA module 202 may solve complex equations that represent the physical behavior of material structures and system. The FEA module 202 may generally receive, as input, three-dimensional (3D) volumetric models of material structures and discretize the models into a graph representation comprising a finite number of elements and nodes. The finite element structures may also be associated with material properties such as mechanical properties (stress-strain tensor), density, thermal conductivity, electromagnetic properties, and the like, such that the structures can be assigned to corresponding elements for simulating real-world behavior. The finite element structures may further also be associated with boundary conditions (e.g., constraints and loading conditions expected to be experienced by the structure in practice). Using such inputs, the FEA module 202 may simulate behavior of the material and analyze the effect of various changes in properties on the material.

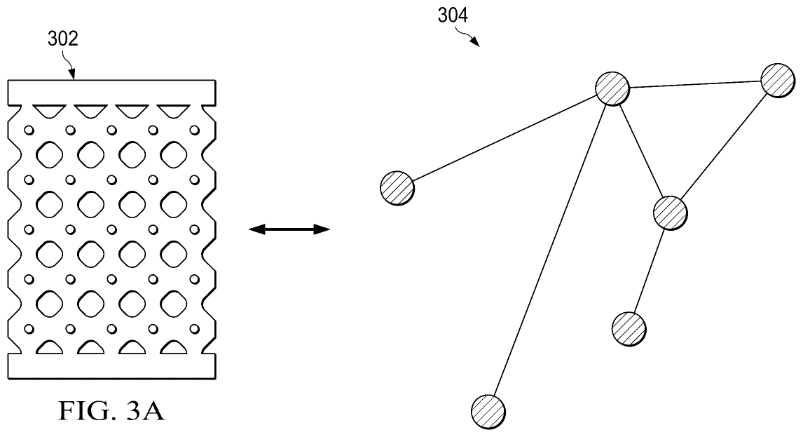

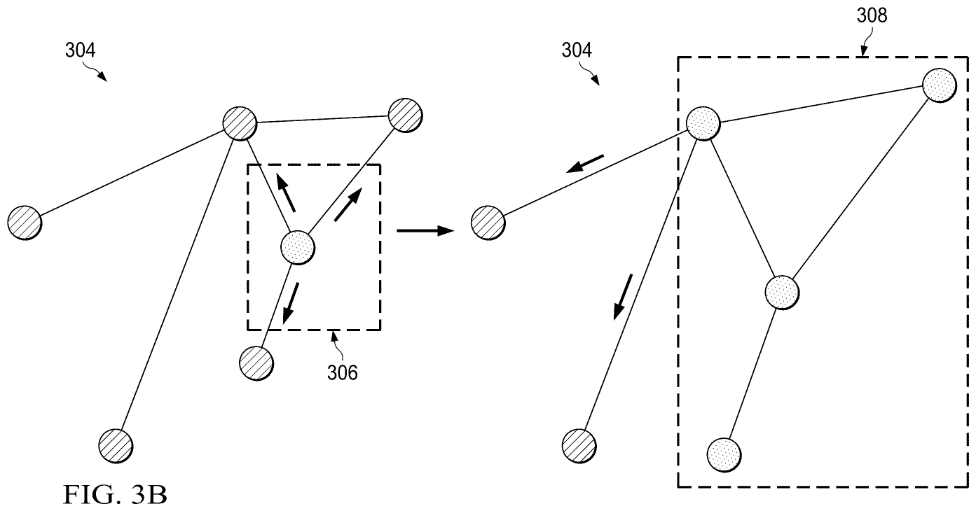

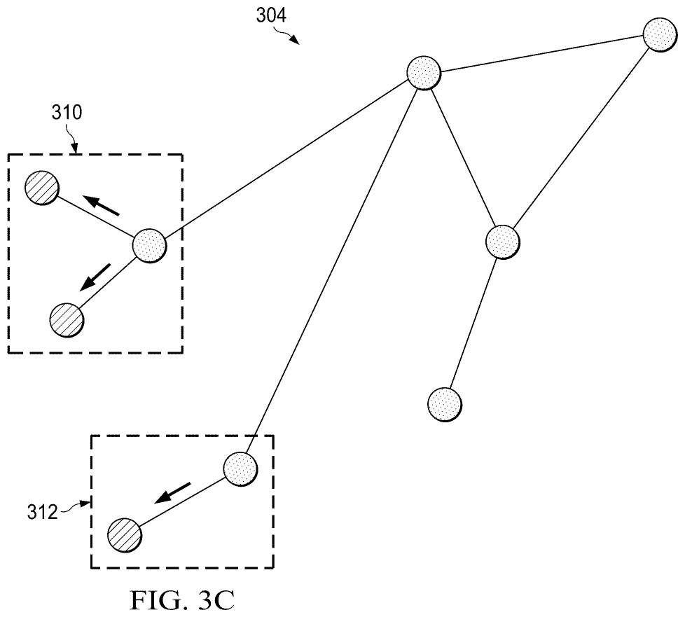

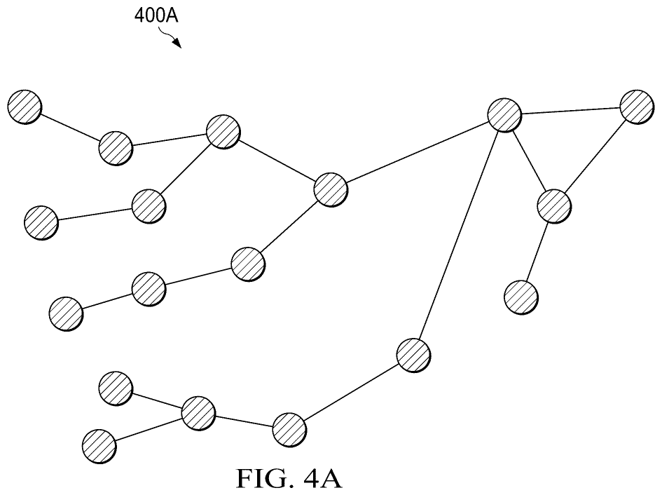

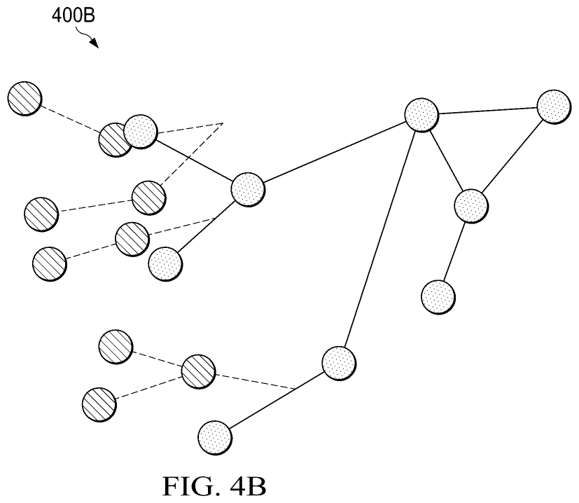

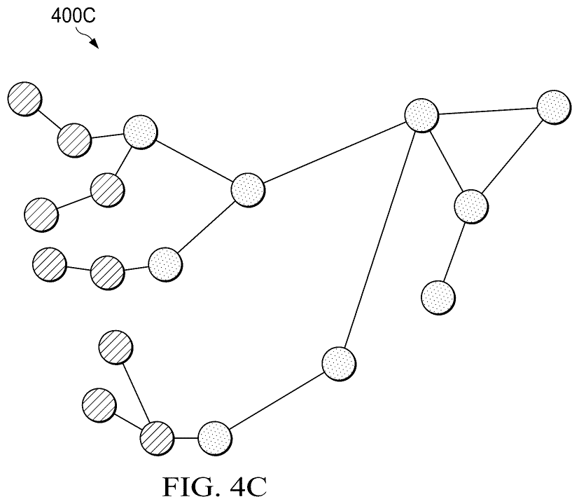

Further, the FEA module 202 may optimize properties of material structures, e.g., such that the material structures achieve a desired performance according to specified conditions or constraints. For example, the FEA module 202 may expand finite element structural size in groupings of nodes having high mechanical stress invariant (e.g., von Mises stress) (e.g., in which a stress measure exceeds a specified threshold). As another example, the FEA module 202 may reduce finite element structural size in areas of low mechanical stress (e.g., in which a stress measure falls below another specified threshold). By adding material in areas of high mechanical stress and reducing material is areas of low mechanical stress, the FEA module 202 is able to optimize a given material structure to achieve a stronger and stiffer properties. A direct correspondence exists between a finite element structural size and an actual physical size due the simulation by the FEA module 202 being configured to approximate a physical reality. Consequently, when the FEA module 202 alters a finite element structure in size and shape, the FEA module 202 in effect approximates a similar real world change in size and shape. FIGS. 3A-3C and 4A-4C demonstrate examples of how the FEA module 202 may perform optimization of a given material structure.

The illustrative AI engine 204 may be embodied as any software, hardware, or circuitry for carrying out functions also performed by the FEA module 202 (e.g., analysis, simulation, optimizations based on graph expansion and reduction, and so on) using one or more artificial intelligence and/or machine learning techniques. For example, the AI engine 204 may be configured to build graph neural network (GNN) models and process computations on such models from training data 206.

The training data 206 may be embodied as any data used to build and/or refine AI and/or machine learning models by the AI engine 204. For example, the training data 206 may be embodied as finite element graph data representations of material structures, or material structure data, such as finite element mesh data, from which finite element graph data representations can be generated. Particularly, a finite element mesh may comprise multiple nodes, which are generally grouped into tetrahedral elements. Typically, four nodes are used for a given tetrahedral element, though not all elements are necessarily tetrahedral.

Initially, the training data 206 may comprise baseline finite element material structures used as input for generating improved structures, which may in turn be used as inputs for further refining techniques used by the AI engine 204, e.g., by guiding the AI engine 204 towards generating improved structural shapes by training the AI with structures that are already improvements from the baseline structural data.

Referring now to FIGS. 3A-3C, an example of graph-based modification of a FEA structure is shown. The illustrative example depicted in FIGS. 3A-3C provide a simplified representation of nodes and elements for a given structure to more clearly demonstrate the techniques described herein, in which the computing system 100 modifies properties of a structure, such as, for example, increasing structural size of the structure in areas of high mechanical stress and/or reducing structural size in areas of low mechanical stress. In practice, a typical finite element mesh (and graph representation thereof) will have a larger size and amount of nodes.

FIG. 3A depicts an initial expansion of nodes for a finite element graph 304 representing a given FEA structure model 302 (a cellular solid, in this example). In the illustrative embodiment, the model 302 is generated from the traditional finite element mesh where the traditional mesh corresponds to a current component design. Intersections of finite elements of the traditional finite element mesh are represented as nodes in the graph. Edges of finite elements of the traditional finite element mesh are represented by connection between nodes. Features of each graphical node are illustratively extrapolated from their traditional finite element nodes and/or adjacent traditional finite elements. In some embodiments, other suitable techniques for generating the graphical representation may be applied, including for example, directly generating a graphical mesh representing traditional finite element mesh.

In an embodiment, the computing system 100 (e.g., via the FEA module 202 or AI engine 204) may traverse the graph, e.g., using a queue-based breadth-first search to identify groupings of nodes associated with structural elements with the highest mechanical stress (or, if contracting areas of the structure model 302, areas with the lowest mechanical stress). FIG. 3B, at the left-hand portion thereof, depicts an initial expansion of the graph 304. Box 306 depicts an area including a node in the graph 304, in which the area has high mechanical stress and being expanded (represented by the change in pattern fill of the node), which implies an increase in size in structural shape. In expanding the size, nodes are shown to be moved further apart from one another. Conversely (not currently shown), in contracting the size of a given area, nodes in a given area are moved closer to one another. FIG. 3B, at the right-hand portion thereof, depicts a continued expansion of the graph 304, in which the computing system 100 propagates the increase in structural size to neighboring nodes thereof (at box 308). As shown in FIG. 3C, the computing system 100 continues to propagate the increase in size across the structure for all nodes in which the mechanical stress for the corresponding element is above a specified threshold measure (at boxes 310 and 312) or otherwise satisfies some specified condition for modifying the corresponding grouping of nodes.

An issue that may arise from the expansion is that the graph 304 may grow such that nodes will move into the area previously occupied by other nodes (referred to herein as “perimeter nodes”). In an embodiment, to address this issue, the computing system 100 may incrementally perform another breadth-first search to move perimeter nodes until each node is at or near its original position.

Referring now to FIGS. 4A-4C, yet another example of modifying structural properties of a FEA structure is shown. FIG. 4A illustrates an initial graph 400A, representative of a finite element structure prior to modifying properties thereof. In this example, assume that the computing system 100 performs the aforementioned breadth-first search to increase the size the graph 400A in areas of high mechanical stress.

As the graph 400A expands, it is possible that nodes associated with the expansion will encroach upon areas already occupied by other nodes. FIG. 4B illustrates an intermediary graph 400B that depicts this possibility. The nodes having a dotted fill pattern in the graph 400B represent nodes in areas thereof following size expansion, and the nodes having a lined fill pattern represent nodes in areas that have not been affected by the expansion (e.g., due to the nodes being in an area deemed not to need modification). Illustratively, the nodes in the former category have expanded into the area occupied by the yet unaffected portion of the graph.

FIG. 4C illustrates a graph 400C that depicts the perimeter nodes (in lined fill pattern) having been moved to accommodate the expanded section of the graph 400C. In an embodiment, the computing system 100 may move the perimeter nodes partway between the original location and where the nodes would be if moved to completely accommodate the expanded section of the graph 400C, e.g., to move the nodes only as needed such that for a larger graph it would not be necessary to move every node for relatively small changes. In this example, the computing system 100 performs only one additional breadth first search before determining that no further movement of the perimeter nodes is needed.

In expanding (or contracting) finite element graphs in areas of high (or low) mechanical stress, the computing system 100 effectively adds material in corresponding areas of a proposed physical structure. For example, adding material to a particular area may make that area thicker at corresponding points of the structure.

As stated, the graph data (or finite element structure data from which the graph is generated) may be provided to the computer system 100 as input to a neural network, such as a graph neural network (GNN) for further analysis, learning, and optimization. In an embodiment, the AI engine 204, using GNN models, performs the expansion and/or contraction methods described herein to evaluate how the underlying structure responds to mechanical loads. Doing so enables structural improvements to be identified more quickly.

Generally, the output structures by the AI engine 204 may provide approximations of improved structures with varying accuracy. Consequently, the AI engine 204 may increasingly encounter error over time while using the GNN-based techniques without further refinement of the GNN models. In an embodiment, a combination of finite element structure improvement by the FEA module 202 and the AI engine 204 may be deployed to harness the computational speed and efficiency of AI engine 204 with the accuracy afforded by traditional FEA simulation.

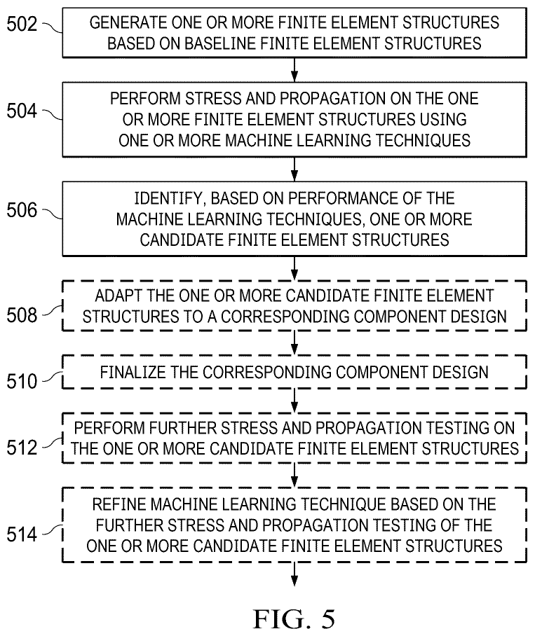

More particularly, the output of the techniques described above may yield improved structures that may be used as training data for the AI engine 204 to refine the improvement methods used thereby. Subsets of the subsequent output by the AI engine 204 may then be further verified by the FEA module 202 to arrive at more accurate results. Turning now to FIG. 5, the computing system 100, in operation, may perform a method 500 for modifying structural and/or functional properties of a finite element structure as part of an AI training loop.

As shown, the method 500 begins in block 502, in which the computing system generates one or more finite element structures based on baseline finite element structures. The baseline finite element structures may comprise an initial set of structural model data, such as structural models that have previously undergone the FEA-based improvement techniques (e.g., the stress and propagation techniques) described above, structural models that have not yet undergone such techniques, and so on. In practice, the AI engine 204 (or FEA module 202) may generate hundreds or thousands of finite element structures from the baseline finite element structure data.

In block 504, the computing system 100 may perform the stress and propagation techniques described above on the generated finite element structures using one or more AI or machine learning techniques. For instance, the AI engine 204 may evaluate the structures with GNNs with the stress and propagation techniques described relative to FIGS. 3A-3C and 4A-4C. More particularly, the AI engine 204 may use the GNNs to traverse a given graph representation of a finite element mesh structure and identify areas for structural and/or functional modification, such as areas of high or low mechanical stress, stiffness, fatigue, deformation, vibration, temperature, optimization of coupled structural-thermal-electromagnetic response, and the like. Once identified, the AI engine 204 may modify such areas, such as by expanding the size of areas of high stress (e.g., by moving affected nodes further part) or contracting the size of areas of low stress (e.g., by moving affected nodes closer).

In block 506, the computing system 100 identifies, based on the performance, one or more candidate finite element structures from the generated structures. For example, the candidates may be determined based on improvement measures in select properties, in stress and stiffness levels of the structure (e.g., the improvement exceeds a specified threshold for stress or stiffness). In an embodiment, the amount of candidates may be considerably smaller compared to the amount of structures generated in block 502. For example, in practice, the computing system 100 may select approximately ten candidates. However, one of skill in the art will recognize that other amounts for selection may be suitable.

In block 508, the computing system 100 optionally adapts the one or more candidate finite element structures to a corresponding component design. For example, areas observed to benefit from increased or decreased material dimensions can be adjusted, geometries can be altered, or other structural parameters adjusted according to the candidate finite element structure.

In block 510, the computing system 100 optionally finalizes the component design. In an embodiment, the computing system 100 may finalize the design, e.g., upon achieving threshold values (e.g., specific stress measures, stress stiffness measures, and other measurable design factors).

In block 512, the computing system 100 optionally performs further stress and propagation testing on the candidate finite element structures. To do so, the computing system 100 may input the one or more candidate finite element structures to the FEA module 202 to perform the stress and propagation methods as well as traditional FEA simulation and improvement methods on the structures. Doing so allows the candidate finite element structures to be more accurately assessed. Note, following this step, the computing system 100 may optionally perform the steps of blocks 508 and 510 in adapting and finalizing a corresponding component design for the structure.

In block 514, the computing system 100 optionally refines the machine learning model based on the further testing of block 508. More particularly, the AI engine 204 may use the output structures of the FEA module 202 from block 508 as baseline training data for updating performance aspects and accuracy of the GNN to mitigate subsequent error.

Advantageously, the method 500 yields finite element structures having improved properties, such as in stress tolerance. The computing system 100 (or other systems receiving the output structures) may adapt such structures in designing a physical material, such as vehicle components, infrastructure materials, and the like.

Although certain embodiments have been described and illustrated in exemplary forms with a certain degree of particularity, it is noted that the description and illustrations have been made by way of example only. Numerous changes in the details of construction, combination, and arrangement of parts and operations may be made. Accordingly, such changes are intended to be included within the scope of the disclosure, the protected scope of which is defined by the claims.

What is claimed is:

1. A method, comprising:
receiving, by one or more processors, a graph representation of a finite element mesh, the graph representation including a plurality of groupings of nodes, each grouping of nodes corresponding to a structural element of the finite element mesh;
traversing the graph representation, wherein the traversal comprises, for each of the plurality of groupings of nodes:
(i) evaluating one or more properties associated with the structural element,
(ii) determining, based on the evaluation of the one or more properties, whether the structural element satisfies a specified condition, and
(iii) upon determining that the structural element satisfies the specified condition, modifying, based on the evaluation, the grouping of nodes in the graph representation; and
outputting the traversed graph representation.

2. The method of claim 1, wherein the finite element mesh corresponds to a vehicular component design, and further comprising adapting the vehicular component design based on the output.

3. The method of claim 1, further comprising:
building a graph neural network (GNN) trained on a plurality of graph representations each corresponding to a finite element mesh;
inputting the graph representation to the GNN; and
receiving an output graph representation from the GNN.

4. The method of claim 3, further comprising repeating steps (i)-(iii) on the output graph representation from the GNN.

5. The method of claim 3, further comprising:
receiving a second output graph representation resulting from the repeating of steps (i)-(iii); and
refining the GNN using the second output graph representation as training data.

6. The method of claim 1, wherein determining whether the structural element satisfies a specified condition comprises determining whether a stress measure associated with the structural element exceeds a specified threshold.

7. The method of claim 6, wherein modifying the grouping of nodes comprises expanding a distance between the grouping of nodes.

8. The method of claim 1, wherein determining whether the structural element satisfies a specified condition comprises determining whether a stress measure associated with the structural element falls below a specified threshold.

9. The method of claim 8, wherein modifying the grouping of nodes comprises contracting a distance between the grouping of nodes.

10. The method of claim 1, wherein the traversal of the graph representation is a breadth-first search.

11. A computing system, comprising:
one or more processors; and
a memory storing a plurality of instructions, which, when executed by the one or more processors, causes the computing system to:
build, from a plurality of graph representations each of corresponding finite element mesh, a graph neural network (GNN), each graph representation including a plurality of groupings of nodes, wherein each grouping of nodes corresponds to a structural element of the corresponding finite element mesh;
generate a second plurality of graph representations each of a corresponding finite element mesh;
input the second plurality of graph representations to the GNN;
receive, from the GNN, a plurality of output graph representations;
select, from the plurality of output graph representations, one or more candidate graph representations; and
for each of the candidate graph representations:
traverse the candidate graph representation, wherein the traversal comprises, for each of the plurality of groupings of nodes:
(i) evaluating one or more properties associated with the structural element,
(ii) determining, based on the evaluation of the one or more properties, whether the structural element satisfies a specified condition, and
(iii) upon determining that the structural element satisfies the specified condition, modifying, based on the evaluation, the grouping of nodes in the graph representation, and
(iv) output the traversed candidate graph representation.

12. The computing system of claim 11, wherein each finite element mesh corresponds to a vehicular component design, and wherein the plurality of instructions further causes the computing system to adapt the vehicular component design based on the output traversed candidate graph representation.

13. The computing system of claim 11, wherein the plurality of instructions further causes the computing system to generate training data from the traversed candidate graph representation.

14. The computing system of claim 13, wherein the plurality of instructions further causes the computing system to refine the GNN based on the generated training data.

15. The computing system of claim 11, wherein to determine whether the structural element satisfies a specified condition comprises to determine whether a stress measure associated with the structural element exceeds a specified threshold.

16. The computing system of claim 15, wherein to modify the grouping of nodes comprises to expand a distance between the grouping of nodes.

17. The computing system of claim 11, wherein to determine whether the structural element satisfies a specified condition comprises to determine whether a stress measure associated with the structural element falls below a specified threshold.

18. The computing system of claim 17, wherein to modifying the grouping of nodes comprises to contract a distance between the grouping of nodes.

19. The computing system of claim 11, wherein the traversal of the graph representation is a breadth-first search.

20. A computer-readable storage medium storing a plurality of instructions, which, when executed on one or more processors, comprises:
build, by the one or more processors and from a plurality of graph representations each of corresponding finite element mesh, a graph neural network (GNN), each graph representation including a plurality of groupings of nodes, wherein each grouping of nodes corresponds to a structural element of the corresponding finite element mesh;
generate a second plurality of graph representations each of a corresponding finite element mesh;
input the second plurality of graph representations to the GNN;
receive, from the GNN, a plurality of output graph representations;
select, from the plurality of output graph representations, one or more candidate graph representations; and
for each of the candidate graph representations:
traverse the candidate graph representation, wherein the traversal comprises, for each of the plurality of groupings of nodes:
(i) evaluating one or more properties associated with the structural element,
(ii) determining, based on the evaluation of the one or more properties, whether the structural element satisfies a specified condition, and
(iii) upon determining that the structural element satisfies the specified condition, modifying, based on the evaluation, the grouping of nodes in the graph representation, and
(iv) output the traversed candidate graph representation.
